(19) United States
(12) Patent Application Publication
(10) Pub. No.: US 2017/0194546 A1
(43) Pub. Date: Jul. 6, 2017

(54) SKUTTERUDITE THERMOELECTRIC MATERIALS AND METHODS FOR MAKING

(71) Applicant: California Institute of Technology, Pasadena, CA (US)

(72) Inventors: Samad A. Fidrosy, Pasadena, CA (US); Jong-Ah Paik, Pasadena, CA (US); Kevin L. Smith, Pasadena, CA (US); Billy Chun-Yip Li, Pasadena, CA (US); Su C. Chi, Pasadena, CA (US); Kevin Yu, Pasadena, CA (US); Jean-Pierre Fleurial, Altadena, CA (US); David M. Uhl, Pasadena, CA (US); Thierry Caillat, Pasadena, CA (US); George H. Nakasukasa, Pasadena, CA (US); Vilapanur A. Ravi, Claremont, CA (US)

(73) Assignee: California Institute of Technology, Pasadena, CA (US)

(21) Appl. No.: 15/398,527

(22) Filed: Jan. 4, 2017

Related U.S. Application Data
(60) Provisional application No. 62/274,900, filed on Jan. 5, 2016.
(60) Provisional application No. 62/274,712, filed on Jan. 4, 2016.

(51) Int. Cl. H01L 35/08; H01L 35/32; H01L 35/34; H01L 35/18

(52) U.S. Cl. CPC H01L 35/08; H01L 35/18; H01L 35/32; H01L 35/34

(57) ABSTRACT

The present invention provides a thermoelectric device. The thermoelectric device includes an interconnect layer, a skutterudite layer, and a metallization stack. The metallization stack, having a diffusion layer, is disposed between and in electrical contact with the interconnect layer and the skutterudite layer of the thermoelectric device. The present invention also provides a method of preparing an SKD thermocouple. The present invention also provides a method of preparing a braze joint.

### CROSS-REFERENCES TO RELATED APPLICATIONS

This application claims priority to U.S. Provisional Application Nos. 62/274,900, filed Jan. 5, 2016, and 62/274,712, filed Jan. 4, 2016, each of which is incorporated herein in its entirety for all purposes.

### STATEMENT AS TO RIGHTS TO INVENTIONS MADE UNDER FEDERALLY SPONSORED RESEARCH AND DEVELOPMENT

The invention described herein was made in the performance of work under a NASA contract NNN12AA01C, and is subject to the provisions of Public Law 96-517 (35 U.S.C. §202) in which the Contractor has elected to retain title.

### BACKGROUND OF THE INVENTION

The electrical, thermal and mechanical behavior of the hot side interface of high temperature power generating thermoelectric (TE) devices has been shown to be a dominant source of performance degradation in long life space and terrestrial power systems. The infusion of more efficient TE materials in such systems and expanding the range of thermoelectrics to other applications requires the development of thermo-chemically stable, mechanically robust and oxidation resistant metallizations. This is the case for p-type (CeFe₃Ru₁Sb₁₂) and n-type (Ce_{0.1}Co^{0.955}Pd_{0.045}Sb_{2.955}Te_{0.045}) skutterudites (SKD) that are currently being considered for replacing the state-of-practice technology in the Multi-Mission Radioisotope Thermoelectric Generator (MMRTG) with a 17-year end-of-design-life (EODL). These TE materials are also of interest for terrestrial applications that operate in oxidizing environments.

Devising a suitable metallization and bonding scheme for SKD materials is made difficult by the complex reactivity of its individual components. Antimony in the SKD reacts with most metals to form antimonide compounds with a wide range of stoichiometries, with some of these compounds being mechanically brittle.

Although choosing metals which react to form high melting point antimonides could be employed to form a reaction bond, it is difficult to limit the reactivity of antimony in SKD such that the metal electrode would not be completely consumed at a nominal operating temperature of up to 650° C. through extensive interdiffusion. Metallization must also be thermo-mechanically stable in addition to forming an electrically and thermally conductive bond with the TE materials. The metallization technology used in state of the art SKD thermocouples suffer from significant interdiffusion over extended periods of time (1 year out of a 17 year EODL). Furthermore, the current SKD thermocouples are fairly sensitive to oxidation due to the residual moisture and oxygen present in hermetically sealed converter designs.

What is needed is a thermoelectric device having improved thermo-mechanical and thermo-chemical properties without compromising the thermoelectric power and efficiency, and a method of making such a device. Surprisingly, the present invention meets this and other needs.

### BRIEF SUMMARY OF THE INVENTION

In one embodiment, the present invention provides a thermoelectric device. The thermoelectric device includes an interconnect layer, a skutterudite layer, and a metallization stack. The metallization stack, having a diffusion layer, is disposed between and in electrical contact with the interconnect layer and the skutterudite layer of the thermoelectric device.

In another embodiment, the present invention provides a method of preparing an SKD thermocouple. The method includes contacting a skutterudite powder and a diffusion metal foil at a temperature of at least about 600° C. and a pressure of from about 1000 psi to about 20,000 psi. The contacting forms the SKD thermocouple.

In another embodiment, the present invention provides a method of preparing a braze joint. The method includes contacting an SKD thermocouple with a braze metal foil, and an interconnect layer. The braze metal foil is disposed between the SKD thermocouple and the interconnect layer at a temperature of about 650° C. and a pressure of about 200 psi.

### BRIEF DESCRIPTION OF THE DRAWINGS

FIG. 1 shows the oxidation-resistant and more thermo-chemically stable multilayer SKD metallization scheme compared to the current state of the art “baseline” SKD couple technology.

FIG. 2 shows the mirrored multilayered metallization stack configuration scheme for the p-type skutterudite leg (left) and the n-type skutterudite leg (right) of the SKD thermocouple.

FIGS. 3A-M show multilayered metallization stacks of thermoelectric devices in a variety of configurations. FIG. 3A shows a thermoelectric device with a metallization stack comprised of a diffusion layer. FIG. 3B shows a thermoelectric device with a metallization stack comprised of a diffusion layer and an adhesion layer. FIG. 3C shows a thermoelectric device with a metallization stack comprised of a capping layer and a diffusion layer. FIG. 3D shows a thermoelectric device with a metallization stack comprised of a capping layer, a diffusion layer, and an adhesion layer, respectively. FIG. 3E shows a thermoelectric device with a metallization stack comprised of a capping layer, an adhesion layer, and a diffusion layer, respectively. FIG. 3F shows a thermoelectric device with a metallization stack comprised of a capping layer, a first adhesion layer, a second adhesion layer, and a diffusion layer, respectively. FIG. 3G shows a thermoelectric device with a metallization stack comprised of a capping layer, a diffusion layer, a first adhesion layer, and a second adhesion layer, respectively. FIG. 3G shows a thermoelectric device with a metallization stack comprised of a capping layer, a diffusion layer, a first adhesion layer, and a second adhesion layer, respectively. FIG. 3H shows a thermoelectric device with a metallization stack comprised of a capping layer, a first adhesion layer, a diffusion layer, and a second adhesion layer, respectively. FIG. 3I shows a thermoelectric device with a metallization stack comprised of a capping layer, a first diffusion layer, an adhesion layer, and a second diffusion layer, respectively. FIG. 3J shows a thermoelectric device with a braze joint and a metallization stack comprised of a diffusion layer. FIG. 3K shows a thermoelectric device with a braze joint and a metallization stack comprised of a diffusion layer and an adhesion layer. FIG. 3L shows a thermoelectric device with a braze joint and a metallization stack comprised of a capping layer and diffusion layer. FIG. 3M shows a thermoelectric device with a braze joint and a metallization stack comprised of a capping layer, a diffusion layer, and an adhesion layer, respectively.

FIG. 4A shows a macro image of a hot pressed metallized p-type SKD puck and FIG. 4B shows machined metallized SKD leg elements from the hot pressed metallized p-type SKD puck.

FIG. 5 shows the power of a SKD thermocouple comprised of a W diffusion layer compared to the power of a thermocouple comprised of a Zr diffusion layer.

FIG. 6 shows the process of the SKD thermocouple fabrication.

FIG. 7 shows the loading pressure and temperature profile as a function of time for the SKD thermocouple bonding.

FIG. 8 shows an image of an assemble SKD thermocouple.

### DETAILED DESCRIPTION OF THE INVENTION

### I. General

The present invention provides a thermoelectric device and methods of making a thermoelectric device that is comprised of multiple metal layers, such as an interconnect layer, a skutterudite layer, and a metallization stack. The resulting thermoelectric device can be resistant to degradation related to both oxidation and interdiffusion of the thermoelectric materials comprising the device. The multi-layer thermoelectric device can include a diffusion layer comprised of metals such as W, Nb, and CeSb, which serve as an interdiffusion barrier. The electrical contacts between each metal layer of the skutterudite thermocouple are formed by a high temperature and high pressure method.

The interconnect layer and the skutterudite thermocouple of the thermoelectric device are annealed together by a braze joint. The braze joint is comprised of an alloy and will form a bond between the interconnect layer and the skutterudite thermocouple by methods using mild temperatures and pressures.

### II. Definitions

“Thermoelectric device” refers to an apparatus comprised of solid state materials which are capable of relying on a temperature gradient to convert thermal energy into electrical energy.

“Thermoelectric material” refers to a material that allows both thermal conduction and electrical conduction.

“Interconnect layer” refers to a structure of a single thickness of the thermoelectric device that lays across a single thermoelement and a second single thermoelement, thereby connecting the two thermoelements to form a thermocouple.

“Skutterudite layer” refers to a feature comprised of a skutterudite material of a single thickness that lays or lies over or under another layer.

“Skutterudite” or “SKD” refers to a mineral typically comprising Co, Ni, or Fe, and P, Sb or As, which has thermoelectric properties. The mineral lattice of skutterudite may be described in its naturally occurring state as unfilled because there are voids in the lattice. These voids may be filled by elements that comprise low-coordination ions. Filled skutterudites may be comprised of a rare earth metal, an alkaline-earth metal, and/or alkali metal, a transition metal and a metalloid. Filled skutterudites may produce either n-type or p-type thermoelectric materials. An example of an n-type skutterudite may be Ce_{0.1}Co_{0.955}Pd_{0.45}Sb_{2.955}Te_{0.045} and an example of a p-type skutterudite may be CeFe₃Ru₁Sb₁₂. The skutterudite material may be in powder form.

“Metallization stack” refers to a plurality of metal material layers, in which each layer of a metal material is adjacent to a second layer of a metal material. Each layer of the metallization stack is of a single thickness that lays or lies over or under another layer.

“Adjacent” refers to items which are in close proximity to one another and preferably in direct physical contact with one another.

“Diffusion layer” or “diffusion barrier layer” refers to a feature comprised of a material that substantially blocks or slows the diffusion of one type of atom or molecule within one region or layer to an undesired region or layer. The diffusion layer is of a single thickness that lays or lies over or under another layer. For example, a diffusion layer will prevent the antimony atoms of a skutterudite layer from diffusing into and through adjacent layers. A diffusion layer is comprised of a material which will be unreactive to the antimony atoms of a skutterudite layer.

“Dispose” refers to any method of placing one element next to and/or adjacent (including on top of) another, and includes, spraying, layering, depositing, painting, dipping, bonding, coating, etc.

“Electrical contact” refers to physical contact sufficient to conduct available current from one material to the next.

“Metal” refers to elements of the periodic table that are metallic and that can be neutral, or negatively or positively charged as a result of having more or fewer electrons in the valence shell than is present for the neutral metallic element. Metals useful in the present invention include the alkali metals, alkali earth metals, transition metals and post-transition metals. Alkali metals include Li, Na, K, Rb and Cs. Alkaline earth metals include Be, Mg, Ca, Sr and Ba.

Transition metals include Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au, Hg and Ac. Post-transition metals include Al, Ga, In, Tl, Ge, Sn, Pb, Sb, Bi, and Po. Rare earth metals include Sc, Y, La, Ce, Pr, Nd, Sm, Eu, Gd, Tb, Dy, Ho, Er, Tm, Yb and Lu. One of skill in the art will appreciate that the metals described above can each adopt several different oxidation states, all of which are useful in the present invention. In some instances, the most stable oxidation state is formed, but other oxidation states are useful in the present invention.

“Metalloid” refers to elements of the periodic table with properties that are in between or a mixture of those of metals and nonmetals, and which is considered to be difficult to classify unambiguously as either a metal or a nonmetal. Metalloids may include specifically Si, B, Ge, Sb, As, and Te, for example.

“P-type” refers to a thermoelectric material in which there is a deficiency of electrons, or an excess of electron holes.

“N-type” refers to a thermoelectric material in which there is an excess of electrons.

“Adhesion layer” refers to a feature comprised of a material which serves to provide adhesion and reactivity between any two or more components or layers to which it is adjacent. An adhesion layer is of a single thickness that lays or lies over or under another layer.

“Capping layer” refers to a feature comprised of a material which serves to provide electrical conductivity between any two or more components or layers to which it is adjacent and throughout the thermoelectric device. A capping layer is of a single thickness that lays or lies over or under another layer.

“Braze joint” refers to a junction of two or more layers which has been produced by heating juxtaposed layers and an alloy, the applied heat being capable to enable an alloy to wet the layers to be joined.

“Alloy” refers to a homogenous mixture or metallic solid solution composed of two or more elements. The mixture of the two or more materials of an alloy is sufficiently intimate that the material shows no visible boundaries between component materials, and no boundaries bend or diffract light passing through the alloy. The term is not limited to purely metallic alloys—i.e., an alloy can also include other elements and/or impurities, such as, for example, silicon. Examples of elements used to comprise an alloy are Ag, Al, Cu, Ni, Si, Sn, Ti, Cr, Fe, Mo, In and C. Examples of alloys are CuSil, CuSil-ABA, InCuSil-ABA, Nicutin, stainless steel.

“Thermocouple” refers to a pair of thermoelectric elements comprised of a pair of dissimilar electrical conductors, which are connected electrically in series and thermally in parallel. The electrical conductors of the thermocouple can be two metals that are joined at a junction point, producing a voltage which varies as a function of temperature at the junction. An example of dissimilar electrical conductors is a pair of one n-type thermoelement and one p-type thermoelement.

“Thermoelement,” “die,” or “leg” refer to an individual block of thermoelectric material. The term “dice” is used herein to refer to a plurality of a single die.

“Metal foil” refers to a thin and flexible sheet of metal.

### III. Thermoelectric Device

The present invention provides a thermoelectric device having a diffusion layer disposed between an interconnect layer and a skutterudite layer to improve oxidation stability of the thermoelectric device. In some embodiments, the present invention provides a thermoelectric device having an interconnect layer, a skutterudite layer, and a metallization stack, where the metallization stack can include a diffusion layer. The metallization layer can be disposed between and in electrical contact with the interconnect layer and the skutterudite layer.

Any suitable interconnect layer is useful in the thermoelectric device of the present invention. Representative metals for the interconnect layer can include transition metals. The interconnect layer can include any combination of metals, such as, but not limited to, Ni, Au, Ag, Cu, Al, Pt, Pd, In, Hf, V, Ti, Cr, or Ta. In some embodiments, the interconnect layer can be at least one metal selected from Ni, Au, Al, or Cu. In some embodiments, the interconnect layer can include Ni.

The interconnect layer can be of any suitable thickness. For example, the interconnect layer can be at least about 100 μm thick, or at least about 200 μm, 300 μm, 400 μm, 500 μm, 600 μm, 700 μm, 800 μm, 900 μm, 1 mm, 5 mm, or 10 mm thick. The interconnect layer can have a thickness of from about 100 μm to about 10 mm, or from about 500 μm to about 5 mm, or from about 750 μm to about 2 mm. In some embodiments, the interconnect layer can have a thickness of from about 100 μm to about 10 mm. In some embodiments, the interconnect layer can have a thickness of about 1 mm thick. In some embodiments, the interconnect layer can have a thickness of about 800 μm.

Any suitable skutterudite layer is useful in the thermoelectric device of the present invention. In some embodiments, the skutterudite layer of the thermoelectric device can be any suitable p-type skutterudite material. In some embodiments, the skutterudite layer is the p-type skutterudite of CeFe₃Ru₁Sb₁₂. In some embodiments, the skutterudite layer of the thermoelectric device can be any suitable n-type skutterudite material. In some embodiments, the skutterudite layer is the n-type skutterudite of Ce_{0.1}Co_{0.955}Pd_{0.045}Sb_{2.955}Te_{0.045}.

The skutterudite layer can have any suitable thickness. For example, the skutterudite layer can be at least about 1 mm thick, or at least about 2, 5, 7, 10, 20, 30, 40, 50, 60, 70, 80, 90, or 100 mm thick. The skutterudite layer can have a thickness of from about 1 mm to about 100 mm, or from about 5 mm to about 80 mm, or from about 7 mm to about 60 mm, or from about 10 mm to about 40 mm. In some embodiments, the skutterudite layer may have a thickness of from about 1 mm to about 100 mm. In some embodiments, the skutterudite layer can have a thickness of about 13 mm. A skutterudite layer can be about 12.7 mm thick.

Any suitable metallization stack is useful in the thermoelectric device of the present invention. The metallization stack can be disposed between and in electrical contact with the interconnect layer and the skutterudite layer. The metallization stack can have at least one diffusion layer, and optionally include at least one adhesion layer in addition to the diffusion layer and at least one capping layer in addition to the diffusion layer. In some embodiments of invention, the metallization stack includes a diffusion layer.

The diffusion layer of the metallization stack can be any suitable metal that improves oxidation stability of the thermoelectric device. A thermoelectric device of the present invention having improved oxidation stability can retain a certain percentage of the initial thermocouple operating power after a period of time. In certain embodiments, after about 50 hours, the thermoelectric device of the present invention can retain a percent of the initial thermocouple operating power of at least about 10%, or at least about 20, 30, 40, 50, 60, 70, 80, or 90%. After about 50 hours, the thermoelectric device of the present invention can retain a percent of the initial thermocouple operating power of from about 10% to about 90%, or from about 20% to about 80%, or from about 30% to about 70%, or from about 40% to about 50%. In some embodiments, after about 50 hours, the thermoelectric device of the present invention can retain a percent of the initial thermocouple operating power of from about 20% to about 80%. In some embodiments, after about 50 hours, the thermoelectric device of the present invention can retain a percent of the initial thermocouple operating power that is of from about 80%.

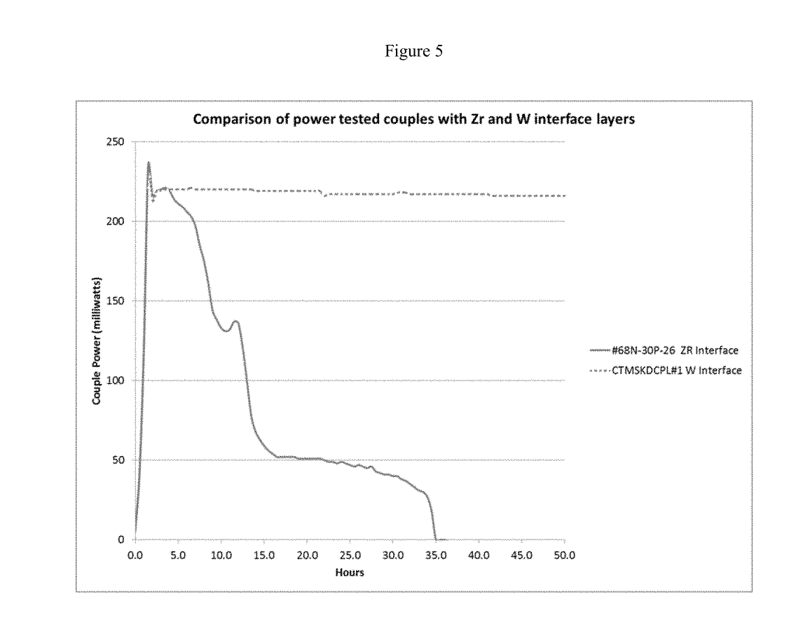

Representative metals for the diffusion layer can include transition metals. Other representative metals for the diffusion layer can include rare earth metals. In some embodiments, the diffusion layer can include metalloids. The diffusion layer may include any combination of transition metals, rare earth metals, and/or metalloids. The diffusion layer can include any combination of metals and metalloids, such as, but not limited to, W, Mo, Re, Nb, Ta, Sb, Ce, Au, Ag, Cu, Al, Pt, Pd, In, Hf, V, Ti, or Cr. In some embodiments, the diffusion layer can be at least one metal selected from W, Nb, Re, and CeSb. In other embodiments, the diffusion layer can include W and Nb. In some embodiments, the diffusion layer can be W. FIG. 5 shows the thermocouple power of the thermoelectric device of the present invention having a diffusion layer made of W, where it retains more than 80% of the initial thermocouple operating power after about 50 hours. FIG. 5 also shows the thermocouple power of a current thermoelectric device having a diffusion layer made of Zr, where it retains 0% of the initial thermocouple operating power after about 50 hours.

The diffusion layer can have any suitable thickness. For example, the diffusion layer can be at least about 1 μm thick, or at least about 2, 5, 7, 10, 20, 30, 40, 50, 60, 70, 80, 90, or 100 μm thick. The diffusion layer can have a thickness of from about 1 μm to about 100 μm, or from about 5 μm to about 80 μm, or from about 10 μm to about 60 μm, or from about 20 μm to about 40 μm. In some embodiments, the diffusion layer can have a thickness from about 1 μm to about 100 μm. In some embodiments of the invention, the diffusion layer can have a thickness of about 25 μm. In other embodiments, the diffusion layer can be about 5 μm thick.

In certain embodiments of the invention, the metallization stack can include an adhesion layer in addition to the diffusion layer to ensure chemical reactivity between the layers of the metallization stack. In some embodiments, the adhesion layer of the metallization stack can be disposed between and in electrical contact with the diffusion layer and the skutterudite layer.

The adhesion layer of the metallization stack can be any suitable metal. Representative metals for the adhesion layer can include transition metals. The adhesion layer can include any combination of metals, such as, but not limited to, Cr, Mo, V, Nb, Ta, Ni, Pd, Pt, Ti, or Hf. In some embodiments, the adhesion layer can be at least one metal selected from Mo, Nb, Ni, and Ti. In other embodiments, the adhesion layer can include Ni and Ti. In some embodiments, the adhesion layer can be Ti.

The adhesion layer of the metallization stack can have any suitable thickness. For example, the adhesion layer can be from about 1 μm thick, or from about 2, 5, 10, 20, 30, 40, 50, 60, 70, 80, 90, or 100 μm thick. The adhesion layer can have a thickness of from about 1 μm to about 100 μm, or from about 2 μm to about 90 μm, or from about 5 μm to about 60 μm, or from about 10 μm to about 30 μm. In some embodiments, the adhesion layer can have a thickness of from about 1 μm to about 100 μm. For example, the adhesion layer of the metallization stack can be about 25 μm thick or less. In some embodiments, the adhesion layer can have a thickness of about 25 μm. In other embodiments, the adhesion layer can be about 11.4 μm thick.

In certain embodiments of the invention, the metallization stack can include a capping layer in addition to the diffusion layer to facilitate electrical conductivity throughout the thermoelectric device. In some embodiments, the capping layer of the metallization stack can be disposed between and in electrical contact with the interconnect layer and the diffusion layer.

The capping layer of the metallization stack can be any suitable metal. Representative metals for the capping layer can include transition metals. The capping layer can include any combination of metals, such as, but not limited to, Ti, Hf, Cr, Mo, W, V, Nb, Ta, Ni, Pd, Pt, Fe, Co, or Cu. A suitable combination of metals that can be in the capping layer can be, for example, stainless steel. In some embodiments, the capping layer can be at least one metal selected from Ti, Ni, and stainless steel. In some embodiments, the stainless steel can be a commercially available stainless steel referred to as SS340. In other embodiments, the capping layer can include Ni and Ti. In some embodiments, the capping layer can be SS340. In some embodiments, the capping layer can be Ti.

The capping layer of the metallization stack can have any suitable thickness. For example, the capping layer can be from about 1 μm thick, or from about 10, 50, 100, 200, 300, 400, 500, 600, 700, 800, 900, or 1000 μm thick. The capping layer can have a thickness of from about 1 μm to about 1000 μm, or from about 10 μm to about 800 μm, or from about 50 μm to about 600 μm, or from about 100 μm to about 400 μm. In some embodiments, the capping layer can have a thickness of from about 1 μm to about 1000 μm. For example, the capping layer of the metallization stack can be about 100 μm thick or more. In other embodiments, the capping layer can be about 50 μm thick or about 125 μm thick. In some embodiments, the capping layer can have a thickness of 125 μm. In other embodiments, the capping layer can have a thickness of 50 μm.

In the following embodiments of the present invention, each presented layer within the thermoelectric device is described as being disposed between and in electrical contact with each layer directly adjacent to and on either side of the presented layer.

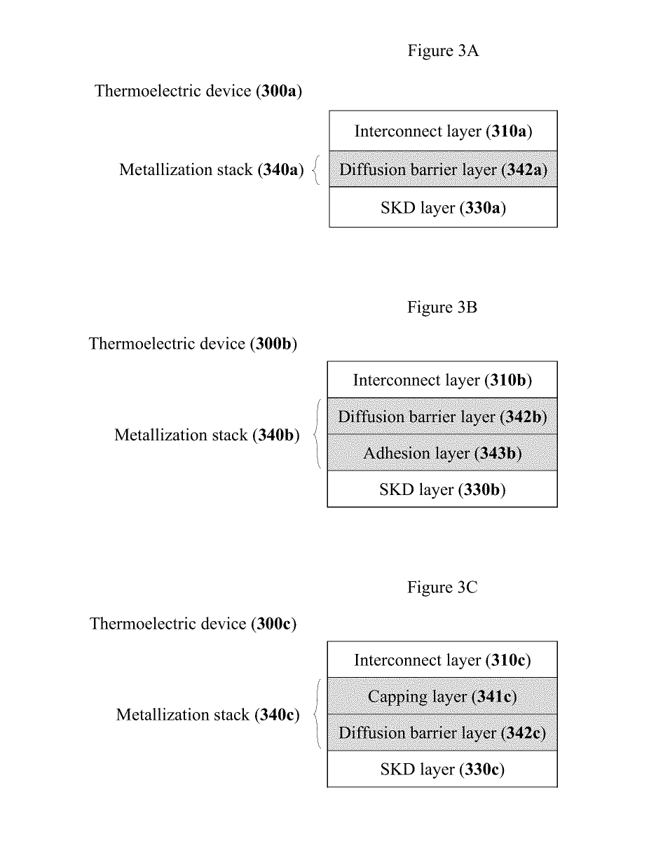

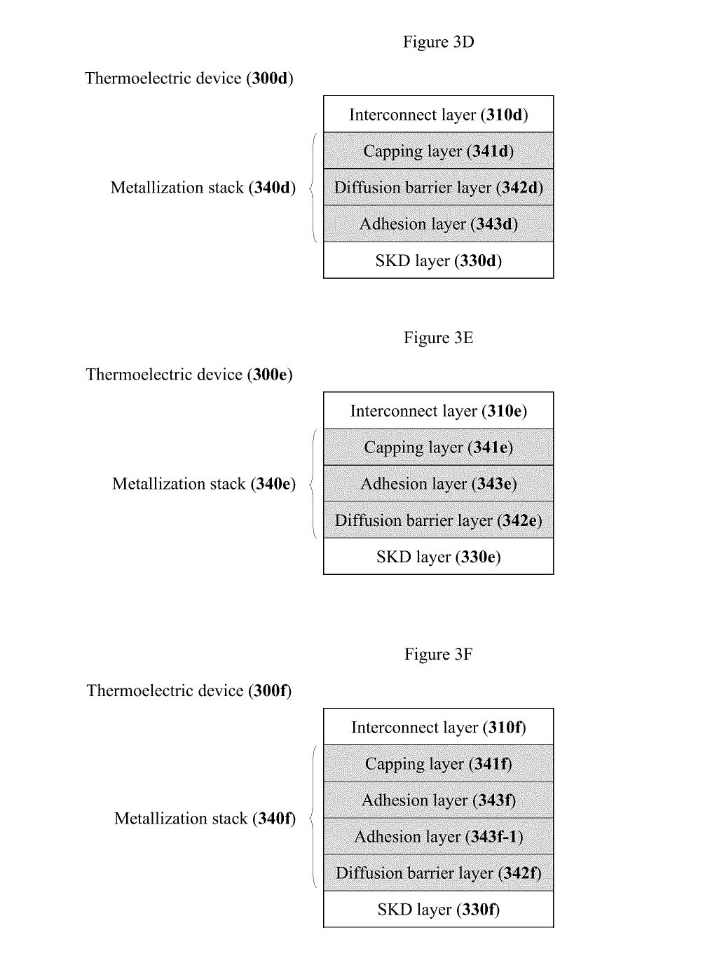

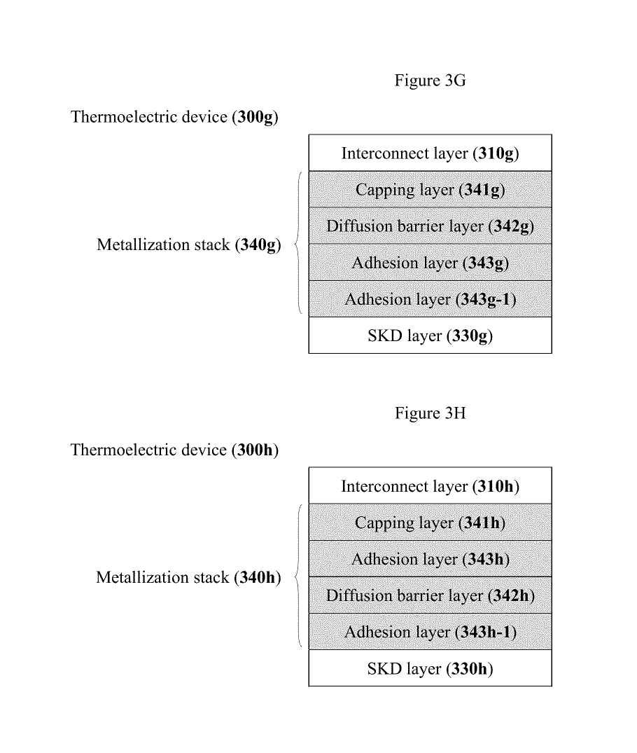

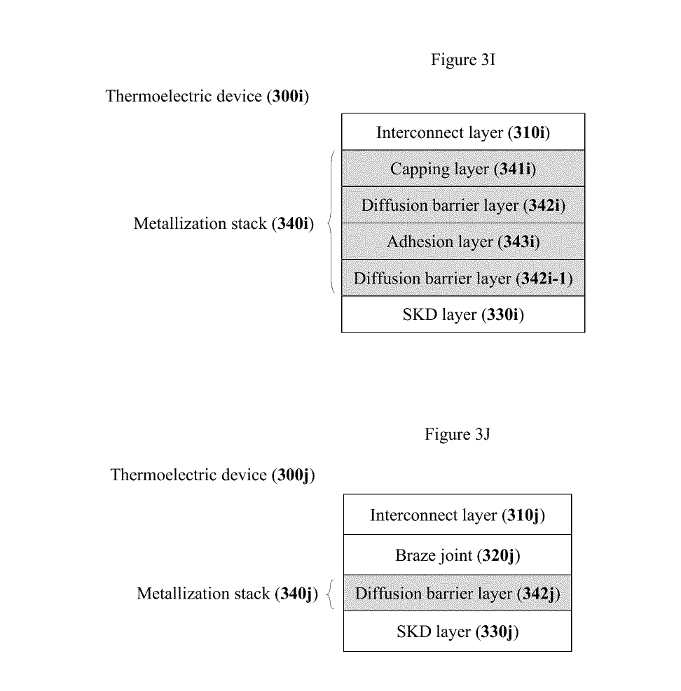

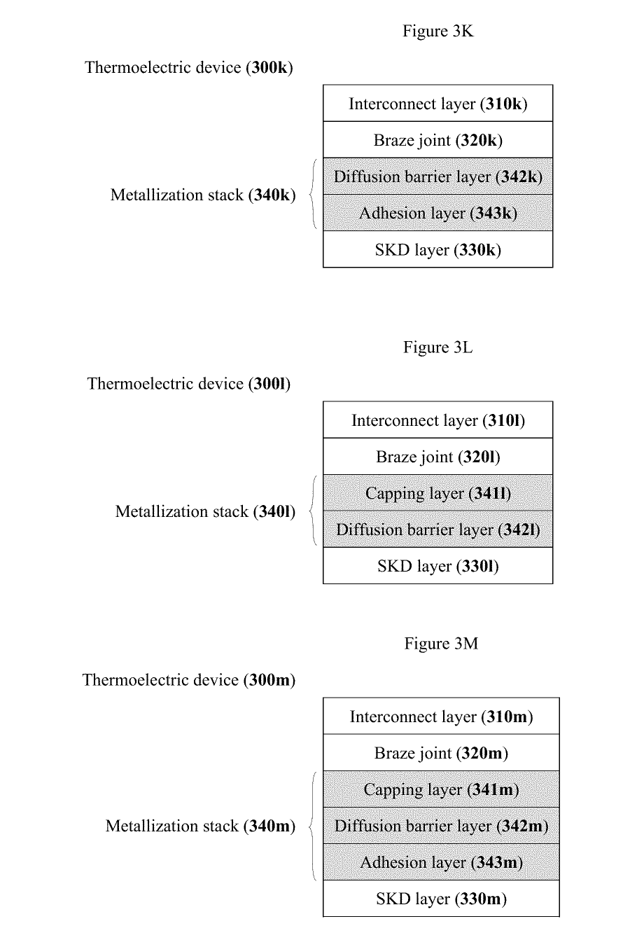

In some embodiments of the invention, the metallization stack can have at least one diffusion layer between the interconnect layer and the SKD layer. FIG. 3A of thermoelectric device 300a shows the metallization stack 340a having at least one diffusion layer 342a. Diffusion layer 342a is between interconnect layer 310a and SKD layer 330a. As shown in FIG. 3B, the metallization stack 340b of thermoelectric device 300b can include a diffusion layer 342b and an adhesion layer 343b. The diffusion layer 342b is between interconnect layer 310b and adhesion layer 343b, and the SKD layer 330b is located on the opposite side of adhesion layer 343b. In another embodiment of the invention, as shown in FIG. 3C, the metallization stack 340c of the thermoelectric device 300c has a capping layer 341c and a diffusion layer 342c. The capping layer 341c is located between the interconnect layer 310c and the diffusion layer 342c, with the SKD layer 330c located on the opposite side of the diffusion layer 342c.

In some embodiments of the invention, the metallization stack can have at least one diffusion layer, at least one capping layer, and at least one adhesion layer. For example, the thermoelectric device 300d of FIG. 3D has a metallization stack 340d which includes a capping layer 341d on top of a diffusion layer 342d, and an adhesion layer 343d under the diffusion layer 342d. The interconnect layer 310d is located above and on the opposite side of the capping layer 341d. The SKD layer 330d is located under and on the opposite side of the adhesion layer. In another embodiment of the invention, as shown in FIG. 3E, the metallization stack 340e of thermoelectric device 300e can include at least one capping layer 341e, at least one adhesion layer 343e, and at least one diffusion layer 342e, where the at least one adhesion layer 343e is between the capping layer 341e and the diffusion layer 342e. The interconnect layer 310e is located on the side of the capping layer 341e opposite the adhesion layer 343e. The SKD layer 330e is located on the side of the diffusion layer 342e opposite the adhesion layer 343e.

In some embodiments the metallization stack can have more than one adhesion layer, in addition to also having at least one diffusion layer and at least one capping layer. An example of this embodiment is shown in FIG. 3F, where the metallization stack 340f of thermoelectric device 300f includes a capping layer 341f, a first adhesion layer 343f, a second adhesion layer 343f-1, and a diffusion layer 342f, respectively. The interconnect layer 310f is located on the side of the capping layer 341f opposite the first adhesion layer 343f. The SKD layer 330f is located on the side of the diffusion barrier layer 342f opposite the second adhesion layer 343f-1. In some embodiments, as shown in FIG. 3G, the metallization stack 340g of thermoelectric device 300g can have a capping layer 341g, a diffusion layer 342g, a first adhesion layer 343g, and a second adhesion layer 343g-1, respectively. The interconnect layer 310g is located on the side of the capping layer 341g opposite the diffusion layer 342g. The SKD layer 330g is located on the side of the second adhesion layer 343g-1 opposite the first adhesion layer 343g. In some other embodiments, as shown in FIG. 3H, the metallization stack 340h of thermoelectric device 300h can have a capping layer 341h, a first adhesion layer 343h, a diffusion layer 342h, and a second adhesion layer 343h-1, respectively. The interconnect layer 310h is located on the side of the capping layer 341h opposite the first adhesion layer 343h. The SKD layer 330h is located on the side of the second adhesion layer 343h-1 opposite the diffusion layer 342h.

In some embodiments, the metallization stack can have more than one diffusion layer, in addition to also having at least one adhesion layer and at least one capping layer. An example of this is shown in FIG. 3I, where the metallization stack 340i of thermoelectric device 300i can have a capping layer 341i, a first diffusion layer 342i, an adhesion layer 343i, and a second diffusion layer 342i-1, respectively. The interconnect layer 310i is located on the side of the capping layer 341i opposite the first diffusion layer 342i. The SKD layer 330i is located on the side of the second diffusion layer 342i-1 opposite the adhesion layer 343i.

In certain embodiments of the invention, the thermoelectric device can include a braze joint. The braze joint of the thermoelectric device can be disposed between and in electrical contact with the interconnect layer and the metallization stack. For example, FIG. 3J shows thermoelectric device 300j where the metallization stack 340j has a diffusion layer 342j. The braze joint 320j is between the interconnect layer 310j and the diffusion layer 342j. The SKD layer 330j is located on the side of the diffusion barrier layer 342j opposite the braze joint 320j. In some other embodiments, as shown in FIG. 3K, the thermoelectric device 300k has a braze joint 320k between the interconnect layer 310k and the metallization stack 340k. The metallization stack 340k can include a diffusion layer 342k and an adhesion layer 343k, where the diffusion layer 342k is between the braze joint 320k and adhesion layer 343k, and the SKD layer 330k is located on the opposite side of adhesion layer 343k. As shown in FIG. 3L, the braze joint 320I of the thermoelectric device 300I is between the interconnect layer 310I and the metallization stack 340I, where the metallization stack has a capping layer 341I and a diffusion layer 342I. The capping layer 341I is located between the braze joint 320I and the diffusion layer 342I, with the SKD layer 330I located on the opposite side of the diffusion layer 342I.

The braze joint of the thermoelectric device can be any suitable alloy. Representative metals for the alloy used for the braze joint include transition metals, such as, but not limited to, Ag, Cu, Ni, Pd, Pt, Au, Fe, Cr, Mo, Ti, Co, Mn, and V. Other representative metals for the alloy used for the braze joint can include some post-transition metals, such as Sn, Pb, and In. In some embodiments, the alloy used for the braze joint can include metalloids, such as, but not limited to, Si, B, Ge, and Te. The alloy that can be used for the braze joint may include any combination of transition metals, post-transition metals, and/or metalloids. An alloy that can be useful as the braze joint of the invention can include Ag, Cu, Ni, Si, Sn, Ti, In or combinations thereof. In some embodiments of the invention, an alloy that can be used for the braze joint can include Mg in combination with other elements. In other embodiments of the invention, an alloy that can be used for the braze joint can include Al.

In some embodiments, the braze joint can be an alloy of Ag, Cu, Ni, Si, Sn, Ti, In or combinations thereof. In other embodiments, the braze joint can be an alloy of Cu+Ag (CuSil), Cu+Ag+Ti (CuSil-ABA), Ag+Cu+In+Ti (InCuSil-ABA), Al+Si, Ni+Cu+Sn (Nicutin), Al+Si+Fe, Al+Mg+Cr, Ag, or Sn. In some embodiments, the braze joint can be an alloy of Cu+Ag (CuSil), Cu+Ag+Ti (CuSil-ABA), Al+Si, Ni+Cu+Sn (Nicutin), Ag, and Sn. In some embodiments, the braze joint can be CuSil-ABA.

The braze joint can have any suitable thickness. For example, the braze joint can be at least about 1 μm thick, or at least about 2, 3, 4, 5, 6, 7, 8, 9, 10, 15, 20, 25, 30, 35, 40, 45, 50, 60, 70, 80, 90, or about 100 μm thick. The braze joint can have a thickness of from about 1 μm to about 100 μm, or from about 5 μm to about 80 μm, or from about 10 μm to about 60 μm, or from about 20 μm to about 40 μm. In some embodiments, the braze joint can have a thickness from about 1 μm to about 100 μm. In some embodiments of the invention, the braze joint can have a thickness of about 50 μm.

In some embodiments, as shown in FIG. 3M, the thermoelectric device 300m can include a braze joint 320m located between interconnect layer 310m and metallization stack 340m, where the metallization stack 340m can include a capping layer 341m, a diffusion layer 342m, and an adhesion layer 343m. The capping layer 341m can be located between the braze joint 320m and the diffusion layer 342m. The adhesion layer 343m is located on the side of the diffusion layer 342m opposite the capping layer 341m, and the SKD layer is located on the side of the adhesion layer 343m opposite the diffusion layer 343m.

In some embodiments, the thermoelectric device of the present invention can include an interconnect layer, where the interconnect layer can be Ni. The thermoelectric device can also include a braze joint, where the braze joint can be in electrical contact with the interconnect layer, and the braze joint can be made of CuSil-ABA. The thermoelectric device can also include a metallization stack, where the metallization stack can include a capping layer, a diffusion layer, and an adhesion layer. The capping layer of the metallization stack can be made of stainless steel, and in electrical contact with the braze joint. The diffusion layer of the metallization stack can be W, and in electrical contact with the capping layer. The adhesion layer of the metallization stack can be made of Ti, and in electrical contact with the diffusion layer. The thermoelectric device can also have a skutterudite layer, where the skutterudite layer can be CeFe₃Ru₁Sb₁₂, and the skutterudite layer can be in electrical contact with the adhesion layer.

In some embodiments, the thermoelectric device of the present invention can include an interconnect layer, where the interconnect layer can be Ni. The thermoelectric device can also include a braze joint, where the braze joint can be in electrical contact with the interconnect layer, and the braze joint can be made of CuSil-ABA. The thermoelectric device can also include a metallization stack, where the metallization stack can include a capping layer, a diffusion layer, and an adhesion layer. The capping layer of the metallization stack can be made of Ti, and in electrical contact with the braze joint. The diffusion layer of the metallization stack can be W, and in electrical contact with the capping layer. The adhesion layer of the metallization stack can be Ti, and in electrical contact with the diffusion layer. The thermoelectric device can also have a skutterudite layer, where the skutterudite layer can be Ce_{0.1}Co_{0.955}Pd_{0.045}Sb_{2.955}Te_{0.045}, and the skutterudite layer can be in electrical contact with the adhesion layer.

In some embodiments of the invention, the thermoelectric device can include more than one skutterudite leg. For example, a thermoelectric device can include a first skutterudite leg and a second skutterudite leg, where the skutterudite legs are connected and in electrical contact with an interconnect layer and the interconnect layer is made of Ni. The thermoelectric device can have two braze joints that are in electrical contact with the interconnect layer. The braze joints can be made of CuSil-ABA. The first skutterudite leg can include a metallization stack and a skutterudite layer, where the skutterudite layer is a p-type skutterudite material, CeFe₃Ru₁Sb₁₂. The second skutterudite leg can include a metallization stack and a skutterudite layer, where the skutterudite layer is an n-type skutterudite material, Ce_{0.1}Co_{0.955}Pd_{0.045}Sb_{2.955}Te_{0.045}. Each metallization stack of the first and second skutterudite legs can include a capping layer, a diffusion layer, and an adhesion layer. The capping layer of each metallization stack can be made of stainless steel or Ti, and in electrical contact with a braze joint. The diffusion layer of each metallization stack can be W or Nb, and in electrical contact with the capping layer. The adhesion layer of each metallization stack can be made of Ti, and in electrical contact with the diffusion layer. In some embodiments, the first and second skutterudite legs can include a second metallization stack, in a mirrored orientation and on the side of the SKD layer opposite the first metallization stack.

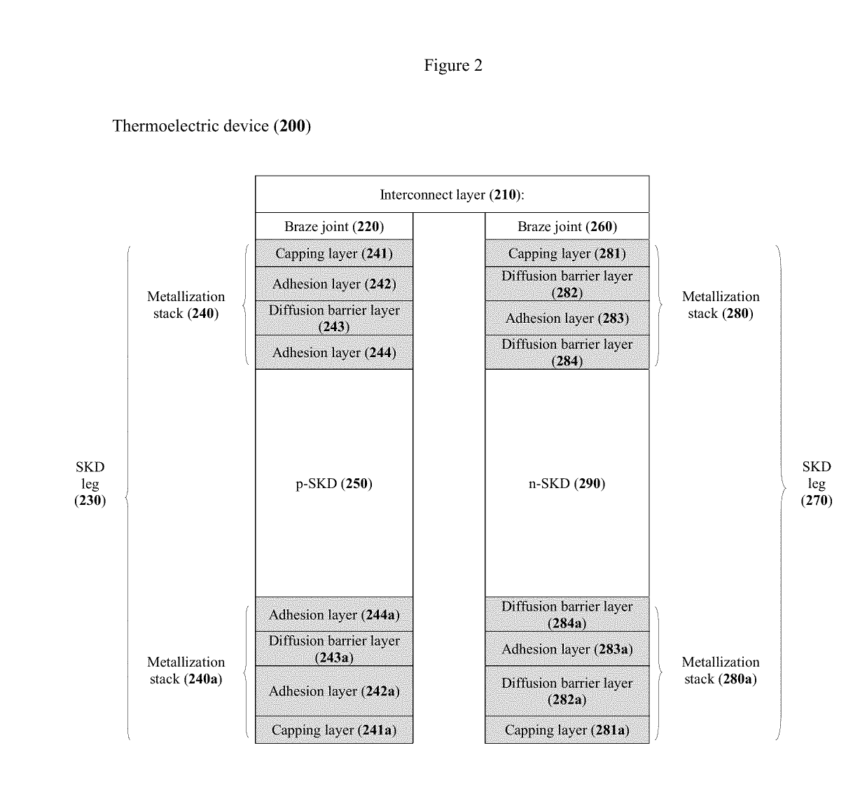

An example of a thermoelectric device with more than one skutterudite leg is shown in FIG. 2, where the SKD legs 230, 270 of the thermoelectric device 200 are attached to an interconnect layer 210 through braze joints 220, 260. The interconnect layer 210 can be Ni and can have a thickness of about 800 μm. The braze joint 220, disposed between and in electrical contact with interconnect layer 210 and capping layer 241, can be made of CuSil-ABA and can be about 50 μm thick. The SKD layer 250 can be p-type skutterudite material CeFe₃Ru₁Sb₁₂, about 12.7 mm thick, and disposed between a first metallization stack 240 and a second metallization stack 240a, wherein the second metallization stack 240a is a mirror image of the first metallization stack 240. Capping layers 241, 241a can be made of SS430 and can be about 50 μm thick. Adhesion layers 242, 242a can be made of Ti and can be about 11.4 μm thick. Diffusion layers 243, 243a can be made of W and can be about 5 μm thick. Adhesion layers 244, 244a can be made of Ti and can be about 25 μm thick. The SKD layer 290 can be n-type skutterudite material Ce_{0.1}Co_{0.955}Pd_{0.045}Sb_{2.955}Te_{0.045}, about 12.7 mm thick, and disposed between a first metallization stack 280 and a second metallization stack 280a, wherein the second metallization stack 280a is a mirror image of the first metallization stack 280. Capping layers 281, 281a can be made of Ti and can be about 125 μm thick. Diffusion layers 282, 282a can be made of W and can be about 5 μm thick. Adhesion layers 283, 283a can be made of Ti and can be about 11.4 μm thick. Diffusion layers 284, 284a can be made of Nb and can be about 5 μm thick.

### IV. Method of Making Thermoelectric Device

The present invention also provides a method of making a SKD thermocouple by hot pressing metal foils for each layer of the metallization stack with the SKD powder. In some embodiments, the method includes contacting a skutterudite powder and a diffusion metal foil. The skutterudite powder and the diffusion metal foil can be contacted at a temperature of at least about 600° C. and a pressure of from about 1000 psi to about 20,000 psi. The contacting can form the SKD thermocouple.

Any suitable skutterudite powder can be used to prepare the SKD thermocouple of the present invention. In some embodiments, the skutterudite powder of the SKD thermocouple can be any suitable p-type skutterudite powder. In some embodiments, the skutterudite powder is the p-type skutterudite of CeFe₃Ru₁Sb₁₂. In some embodiments, the skutterudite powder of the thermoelectric device can be any suitable n-type skutterudite powder. In some embodiments, the skutterudite powder is the n-type skutterudite of Ce_{0.1}Co_{0.955}Pd_{0.045}Sb_{2.955}Te_{0.045}.

Any suitable amount of skutterudite powder can be used. A suitable amount of skutterudite powder will be enough to produce a layer of skutterudite powder that can be at least about 1 mm thick, or at least about 2, 3, 4, 5, 6, 7, 8, 9, 10, 11, 12, 13, 14, 15, 20, 25, 30, 35, 40, 45, 50, 60, 70, 80, 90, or about 100 mm thick. The layer of skutterudite powder can have a thickness of from about 1 mm to about 100 mm, or from about 5 mm to about 80 mm, or from about 7 mm to about 60 mm, or from about 10 mm to about 40 mm. In some embodiments, the layer of skutterudite powder may have a thickness of from about 1 mm to about 100 mm. In some embodiments, the layer of skutterudite powder can have a thickness of about 13 mm. A layer of skutterudite powder can be about 12.7 mm thick.

The diffusion metal foil that can be used to prepare the SKD thermocouple of the present invention can be a foil of any suitable metal that improves oxidation stability of the SKD thermocouple. Representative metals for the diffusion metal foil can include transition metals. Other representative metals for the diffusion metal foil can include rare earth metals. In some embodiments, the diffusion metal foil can include metalloids. The diffusion metal foil may include any combination of transition metals, rare earth metals, and/or metalloids. The diffusion metal foil can include any combination of metals and metalloids, such as, but not limited to, W, Mo, Re, Nb, Ta, Sb, Ce, Au, Ag, Cu, Al, Pt, Pd, In, Hf, V, Ti, or Cr. In some embodiments, the diffusion metal foil can be at least one metal selected from W, Nb, Re, and CeSb. In other embodiments, the diffusion metal foil can include W and Nb. In some embodiments, the diffusion metal foil can be W.

The diffusion metal foil can have any suitable thickness. For example, the diffusion metal foil can be at least about 1 μm thick, or at least about 2, 3, 4, 5, 6, 7, 8, 9, 10, 15, 20, 25, 30, 35, 40, 45, 50, 60, 70, 80, 90, or about 100 μm thick. The diffusion metal foil can have a thickness of from about 1 μm to about 100 μm, or from about 5 μm to about 80 μm, or from about 10 μm to about 60 μm or from about 20 μm to about 40 μm. In some embodiments, the diffusion metal foil can have a thickness from about 1 μm to about 100 μm. In some embodiments of the invention, the diffusion metal foil can have a thickness of about 25 μm. In other embodiments, the diffusion metal foil can be about 5 μm thick.

The skutterudite powder and the diffusion metal foil of the SKD thermocouple can be contacted at any suitable temperature. For example, the skutterudite powder and the diffusion metal foil of the SKD thermocouple can be contacted at a temperature of about 400° C., or about 450, 500, 550, 600, 650, 700, 750, 800, 850, 900, 950, 1000, 1100, or about 1200° C. The skutterudite powder and the diffusion metal foil of the SKD thermocouple can be contacted at a temperature of from about 400° C. to about 1200° C., or from about 450° C. to about 1100° C., or from about 500° C. to about 1000° C., or from about 550° C. to about 900° C., or from about 600° C. to about 800° C. In some embodiments, the skutterudite powder and the diffusion metal foil of the SKD thermocouple can be contacted at a temperature of from at least about 750° C. In some embodiments, the skutterudite powder and the diffusion metal foil of the SKD thermocouple can be contacted at a temperature of from at least about 600° C.

The skutterudite powder and the diffusion metal foil of the SKD thermocouple can be contacted at any suitable pressure. For example, the skutterudite powder and the diffusion metal foil of the SKD thermocouple can be contacted at a pressure of at least about 1000 psi, or about 2000, 3000, 4000, 5000, 6000, 7000, 8000, 9000, 10,000, 11,000, 12,000, 13,000, 14,000, 15,000, 16,000, 17,000, 18,000, 19,000, 20,000, 21,000, 22,000, 23,000, 24,000, 25,000, or about 26,000 psi. The skutterudite powder and the diffusion metal foil of the SKD thermocouple can be contacted at a pressure of from about 1000 psi to about 25,000 psi, or from about 4000 psi to about 20,000 psi, or from about 6000 psi to about 15,000 psi, or from about 8000 psi to about 10,000 psi. In some embodiments, the skutterudite powder and the diffusion metal foil of the SKD thermocouple can be contacted at a pressure of at least about 10,000 psi. In some embodiments, the skutterudite powder and the diffusion metal foil of the SKD thermocouple can be contacted at a pressure of at least about 7500 psi.

The skutterudite powder and the diffusion metal foil of the SKD thermocouple can be contacted for any suitable amount of time. The skutterudite powder and the diffusion metal foil of the SKD thermocouple can be contacted for an amount of time sufficient to form a bond between each interface within the SKD thermocouple. For example, the skutterudite powder and the diffusion metal foil of the SKD thermocouple can be contacted for a length of time of at least about 40 minutes, or about 60 minutes, 80 minutes, 100 minutes, 120 minutes, 3 hours, 6 hours, 12 hours, 18 hours, 24 hours, 30 hours, 36 hours, or about 48 hours. The skutterudite powder and the diffusion metal foil of the SKD thermocouple can be contacted for a length of time of from about 40 minutes to about 48 hours, or from about 60 minutes to about 36 hours, or from about 80 minutes to about 30 hours, or from about 100 minutes to about 24 hours, or from about 120 minutes to about 18 hours. In some embodiments, the skutterudite powder and the diffusion metal foil of the SKD thermocouple can be contacted for a length of time of from about 80 minutes about 24 hours. In some embodiments, the skutterudite powder and the diffusion metal foil of the SKD thermocouple can be contacted for a length of time of about 80 minutes. In some embodiments, the skutterudite powder and the diffusion metal foil of the SKD thermocouple can be contacted for a length of time of about 24 hours.

In some embodiments, the method of making a SKD thermocouple can also include an adhesion metal foil, where the adhesion metal foil is disposed between the diffusion metal foil and the skutterudite powder. The method of making a SKD thermocouple can also include a capping metal foil in addition to the adhesion metal foil, where the capping metal foul can be disposed on a side of the diffusion metal foul opposite the adhesion metal foil.

The adhesion metal foil that can be used to prepare the SKD thermocouple of the present invention can be a foil of any suitable metal. Representative metals for the adhesion metal foil can include transition metals. The adhesion metal foil can include any combination of metals, such as, but not limited to, Cr, Mo, V, Nb, Ta, Ni, Pd, Pt, Ti, or Hf. In some embodiments, the adhesion metal foil can be at least one metal selected from Mo, Nb, Ni, and Ti. In other embodiments, the adhesion metal foil can include Ni and Ti. In some embodiments, the adhesion metal foil can be Ti.

The adhesion metal foil of the SKD thermocouple can have any suitable thickness. For example, the adhesion metal foil can have a thickness of at least about 1 μm, or about 2, 3, 4, 5, 6, 7, 8, 9, 10, 11, 12, 13, 14, 15, 20, 25, 30, 35, 40, 45, 50, 60, 70, 80, 90, or about 100 μm. The adhesion metal foil can have a thickness of from about 1 μm to about 100 μm, or from about 2 μm to about 90 μm, or from about 5 μm to about 60 μm, or from about 10 μm to about 30 μm. In some embodiments, the adhesion metal foil can have a thickness of from about 1 μm to about 100 μm. For example, the adhesion metal foil of the metallization stack can be about 25 μm thick or less. In some embodiments, the adhesion layer can have a thickness of about 25 μm. In other embodiments, the adhesion metal foil can be about 11.4 μm thick.

The capping metal foil that can be used to prepare the SKD thermocouple of the present invention can be a foil of any suitable metal. Representative metals for the capping metal foil can include transition metals. The capping metal foil can include any combination of metals, such as, but not limited to, Ti, Hf, Cr, Mo, W, V, Nb, Ta, Ni, Pd, Pt, Fe, Co, or Cu. A suitable combination of metals that can be in the capping metal foil can be, for example, stainless steel. In some embodiments, the capping metal foil can be at least one metal selected from Ti, Ni, and stainless steel. In some embodiments, the stainless steel can be a commercially available stainless steel referred to as SS340. In other embodiments, the capping metal foil can include Ni and Ti. In some embodiments, the capping metal foil can be SS340. In some embodiments, the capping layer can be Ti.

The capping metal foil of the SKD thermocouple can have any suitable thickness. For example, the capping metal foil can have a thickness of at least about 1 μm, or about 5, 10, 15, 20, 25, 50, 75, 100, 125, 150, 175, 200, 250, 300, 350, 400, 450, 500, 600, 700, 800, 900, or 1000 μm. The capping metal foil can have a thickness of from about 1 μm to about 1000 μm, or from about 10 μm to about 800 μm, or from about 50 μm to about 600 μm, or from about 100 μm to about 400 μm. In some embodiments, the capping metal foil can have a thickness of from about 1 μm to about 1000 μm. For example, the capping metal foil of the SKD thermocouple can have a thickness of at least about 100 μm thick. In other embodiments, the capping metal foil can have a thickness of from about 50 μm to about 125 μm. In some embodiments, the capping metal foil can have a thickness of about 125 μm. In other embodiments, the capping metal foil can be about 50 μm thick.

In some embodiments, the method of making a SKD thermocouple can also include contacting the SKD thermocouple with a braze metal foil, and an interconnect layer. The braze metal foil can be disposed between the SKD thermocouple and the interconnect layer at a temperature of about 650° C. and a pressure of about 200 psi.

The braze metal foil that can be used to prepare the SKD thermocouple of the present invention can be a foil of any suitable alloy. Representative metals for the alloy used for the braze metal foil include transition metals, such as, but not limited to, Ag, Cu, Ni, Pd, Pt, Au, Fe, Cr, Mo, Ti, Co, Mn, and V. Other representative metals for the alloy used for the braze metal foil can include some post-transition metals, such as Sn, Pb, and In. In some embodiments, the alloy used for the braze metal foil can include metalloids, such as, but not limited to, Si, B, Ge, and Te. The alloy that can be used for the braze metal foil may include any combination of transition metals, post-transition metals, and/or metalloids. An alloy that can be useful as the braze metal foil of the invention can include Ag, Cu, Ni, Si, Sn, Ti, In or combinations thereof. In some embodiments of the invention, an alloy that can be used for the braze metal foil can include Mg in combination with other elements. In other embodiments of the invention, an alloy that can be used for the braze metal foil can include Al.

In some embodiments, the braze metal foil can be an alloy of Ag, Cu, Ni, Si, Sn, Ti, In or combinations thereof. In other embodiments, the braze metal foil can be an alloy of Cu+Ag (CuSil), Cu+Ag+Ti (CuSil-ABA), Ag+Cu+In+Ti (InCuSil-ABA), Al+Si, Ni+Cu+Sn (Nicutin), Al+Si+Fe, Al+Mg+Cr, Ag, or Sn. In some embodiments, the braze metal foil can be an alloy of Cu+Ag (CuSil), Cu+Ag+Ti (CuSil-ABA), Al+Si, Ni+Cu+Sn (Nicutin), Ag, and Sn. In some embodiments, the braze metal foil can be CuSil-ABA.

The braze metal foil can have any suitable thickness. For example, the braze metal foil can have a thickness of at least about 1 μm, or at least about 2, 3, 4, 5, 6, 7, 8, 9, 10, 11, 12, 13, 14, 15, 20, 25, 30, 35, 40, 45, 50, 60, 70, 80, 90, or about 100 μm thick. The braze metal foil can have a thickness of from about 1 μm to about 100 μm, or from about 5 μm to about 80 μm, or from about 10 μm to about 60 μm, or from about 20 μm to about 40 μm. In some embodiments, the braze metal foil can have a thickness from about 1 μm to about 100 μm. In other embodiments, the braze metal foil can have a thickness of about 50 μm.

Any suitable interconnect layer is useful in the method of preparing a SKD thermocouple. Representative metals for the interconnect layer can include transition metals. The interconnect layer can include any combination of metals, such as, but not limited to, Ni, Au, Ag, Cu, Al, Pt, Pd, In, Hf, V, Ti, Cr, or Ta. In some embodiments, the interconnect layer can be at least one metal selected from Ni, Au, Al, or Cu. In some embodiments, the interconnect layer can include Ni.

The interconnect layer of the SKD thermocouple can be of any suitable thickness. For example, the interconnect layer can have a thickness of at least about 100 μm, or at least about 200 μm, 300 μm, 400 μm, 500 μm, 600 μm, 700 μm, 800 μm, 900 μm, 1 mm, 5 mm, or about 10 mm. The interconnect layer can have a thickness of from about 100 μm to about 10 mm, or from about 500 μm to about 5 mm, or from about 750 μm to about 2 mm. In some embodiments, the interconnect layer can have a thickness of from about 100 μm to about 10 mm. In some embodiments, the interconnect layer can have a thickness of about 1 mm thick. In some embodiments, the interconnect layer can have a thickness of about 800 μm.

The SKD thermocouple can be contacted with a braze metal foil, and an interconnect layer at any suitable temperature. For example, the SKD thermocouple can be contacted with a braze metal foil, and an interconnect layer at a temperature of at least about 300° C., or about 350, 400, 450, 500, 550, 600, 650, 700, 750, 800, 850, 900, 950, or about 1000° C. The SKD thermocouple can be contacted with a braze metal foil, and an interconnect layer at a temperature of from about 300° C. to about 1000° C., or from about 400° C. to about 900° C., or from about 500° C. to about 800° C., or from about 600° C. to about 700° C. In some embodiments, the SKD thermocouple can be contacted with a braze metal foil, and an interconnect layer at a temperature of about 650° C. In some embodiments, the SKD thermocouple can be contacted with a braze metal foil, and an interconnect layer at a temperature of about 630° C. In some other embodiments, the SKD thermocouple can be contacted with a braze metal foil, and an interconnect layer at a temperature of about 600° C.

The SKD thermocouple can be contacted with a braze metal foil, and an interconnect layer at any suitable pressure. For example, the SKD thermocouple can be contacted with a braze metal foil, and an interconnect layer at a pressure of at least about 100 psi, or about 150, 200, 250, 300, 350, 400, 450, or about 500 psi. The SKD thermocouple can be contacted with a braze metal foil, and an interconnect layer at a pressure of from about 100 psi to about 500 psi, or from about 150 psi to about 450 psi, or from about 200 psi to about 400 psi, or from about 250 psi to about 350 psi. In some embodiments, the SKD thermocouple can be contacted with a braze metal foil, and an interconnect layer at a pressure of about 380 psi. In some embodiments, the SKD thermocouple can be contacted with a braze metal foil, and an interconnect layer at a pressure of about 200 psi.

The SKD thermocouple can be contacted with a braze metal foil, and an interconnect layer for any suitable amount of time. The SKD thermocouple can be contacted with a braze metal foil, and an interconnect layer for an amount of time sufficient to form a bond between each interface within the SKD thermocouple. For example, the SKD thermocouple can be contacted with a braze metal foil, and an interconnect layer for a length of time of at least about 10 minutes, or about 30, 60, 90, 120, 150, 180, 210, 240, 270, or about 300 minutes. The SKD thermocouple can be contacted with a braze metal foil, and an interconnect layer for a length of time of from about 10 minutes to about 300 minutes, or from about 30 minutes to about 270 minutes, or from about 60 minutes to about 240 minutes, or from about 90 minutes to about 210 minutes, or from about 120 minutes to about 180 minutes. In some embodiments, the SKD thermocouple can be contacted with a braze metal foil, and an interconnect layer for a length of time of from about 30 minutes about 60 minutes. In some embodiments, the SKD thermocouple can be contacted with a braze metal foil, and an interconnect layer for a length of time of about 30 minutes.

In some embodiments, the SKD thermocouple can be contacted with a braze metal foil, and an interconnect layer at a temperature that increases incrementally with time. For example, the temperature at which SKD thermocouple can be contacted with a braze metal foil, and an interconnect layer can increase at a rate of about 1° C./minute, or at a rate of about 2, 3, 4, 5, 6, 7, 8, 9, or 10° C./minute. In certain embodiments, the temperature at which SKD thermocouple can be contacted with a braze metal foil, and an interconnect layer can increase at a rate of from about 1° C./minute to 10° C./minute, or from about 3° C./minute to 8° C./minute, or from about 5° C./minute to 6° C./minute. In some embodiments, the temperature at which SKD thermocouple can be contacted with a braze metal foil, and an interconnect layer can increase at a rate of from about 5° C./minute.

### V. Method of Making Braze

The present invention also provides a method of preparing a braze joint. In some embodiments, the method includes contacting the SKD thermocouple with a braze metal foil, and an interconnect layer. The braze metal foil can be disposed between the SKD thermocouple and the interconnect layer at a temperature of about 650° C. and a pressure of about 200 psi. The contacting can form the braze joint. The method of preparing a braze joint is as described above for the method of making a SKD thermocouple that includes contacting the SKD thermocouple with a braze metal foil, and an interconnect layer.

A braze metal foil that can be used to prepare the braze joint for the present invention can be thermo-mechanically stable, chemically stable, electrically conductive and thermally conductive. The braze metal foil can have a melting point that will be sufficiently high to provide strength to the braze metal joint between the SKD thermocouple and the interconnect layer. A braze metal foil can also have a melting point that is lower than that of the SKD thermocouple and the interconnect layer, which are to be joined together by the braze metal foil. The braze metal foil can be homogeneous, wherein the foil is of substantially uniform composition in all dimensions. The braze metal foil can also be ductile, wherein the foil can be bent to a round radius as small as ten times the foil thickness without fracture.

The braze metal foil that can be used to prepare the braze joint of the present invention can be a foil of any suitable alloy and of any suitable thickness as described above. Any suitable interconnect layer is useful in the method of preparing a braze joint. Suitable interconnect layer compositions and thicknesses are described above. The methods for contacting the SKD thermocouple with a braze metal foil, and an interconnect layer so as to form a braze joint as described above.

### VI. Examples

The following examples are offered to illustrate, but not to limit the claimed invention.

### Example 1

### Producing a Multilayered SKD Thermoelectric Material: Metallization Stacks

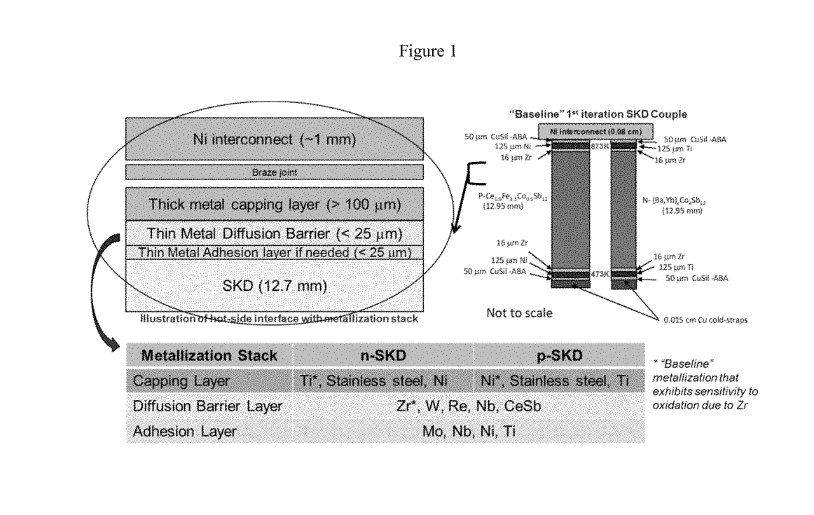

FIG. 1 shows the use of multilayer metallization, where the first thin layer of a metallization stack functions as an adhesion layer between the SKD and the diffusion barrier layer. The second layer (diffusion barrier) prevents formation of antimonides (from the SKD side) and/or the diffusion of metallic elements from the second thicker capping layer and the bonded interface (typically a high temperature metallic braze joint). The third layer functions as a capping layer to facilitate subsequent joining of the thermoelectric device. Additional ultrathin adhesion metal layers are added as necessary to ensure chemical reactivity between the diffusion barrier layer and its two interfaces (SKD and metal cap), while ensuring minimal formation of potential brittle reaction layers.

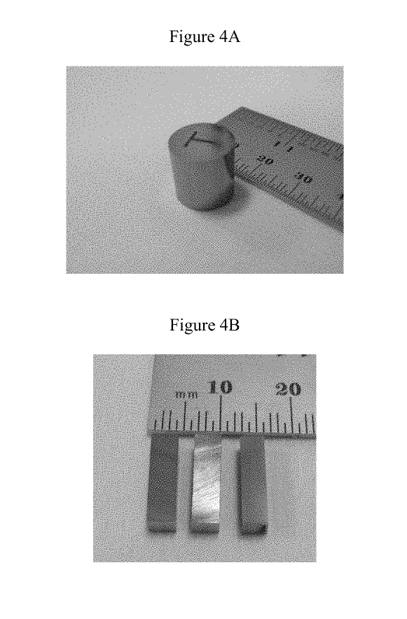

To form the multilayered SKD thermoelectric material, p-type SKD powder materials (CeFe₃Ru₁Sb₁₂) and n-type SKD powder materials (Ce_{0.1}Co_{0.955}Pd_{0.45}Sb_{2.955}Te_{0.045}) were hot pressed with multilayered metal foil metallizations in a single step at temperatures ranging from 600° C. to 800° C. in a graphite die in a uniaxial hot press at a maximum pressure in the 7500 to 20,000 psi range. The multilayered foil metallizations are shown in FIG. 2, where each SKD leg 230, 270 includes a metallization stack 240, 280, a layer of SKD powder 250, 290, and another metallization stack 240a, 280a. Each component of the multilayered foil metallization is described above. The p-type multilayered metal foil metallization is pressed at 750° C. for 80 minutes under a pressure of 10,000 psi to form a p-type puck. The n-type multilayered metal foil metallization is pressed at 750° C. for 24 hours under a pressure of 10,000 psi to form an n-type puck. A macro image of a hot pressed metallized p-type SKD puck is shown in FIG. 4A and machined metallized SKD leg elements from such p-type SKD puck is shown in FIG. 4B.

Thermoelectric devices comprising SKD materials will contain a diffusion layer, also referred to as a diffusion barrier. A diffusion layer has been incorporated in existing SKD devices between the SKD materials and the metal contacts (i.e. metal capping layer) to prevent extensive diffusion of Sb in the skutterudite material at the interfaces of the SKD and the metal capping layers. However, diffusion barriers that are typically used are comprised of Zr, Hf, or Y and do not prevent the degradation of the thermoelectric device caused by oxidation or the formation of brittle reaction layers at the skutterudite interfaces. Alternatively, implementing a diffusion barrier comprised of other metals, such as W or Nb, does prevent the degradation of the thermoelectric device. FIG. 5 is a plot of the oxidation resistance of the novel metallization SKD-thermocouple, wherein the diffusion layer is comprised of W, compared to the state of the art metallization SKD-thermocouple, wherein the diffusion layer is comprised of Zr. The performance of these two couples was measured side by side within the same test chamber with an inert gas atmosphere and a low level of residual oxygen. The new metallizations allow the SKD couple to maintain its performance throughout the test (W-diffusion layer, dotted line). The state of the art metalizations do not allow the SKD couple to maintain its performance throughout the test (Zr-diffusion layer, solid line).

### Example 2

### Producing a Multilayered SKD Thermoelectric Material: Brazing

Several brazes were identified based on several criteria. One important criterion to consider is the braze chemistry and the possible interaction with the SKD and/or the capping layer (Ni, Ti, SS430). Brazes were also selected based on the maximum bonding temperature of 650° C. (lower temperatures preferred) and a continuous operating temperature of 600° C. Finally, the thermoelectric devices need to be able to operate under vacuum. Therefore, ideal brazing materials and other metal components of the SKD thermoelectric device would need to have relatively low vapor pressures to withstand an environment sans pressure.

When the braze material CuSil-ABA was tested, it was found that TiCu compounds formed in the capping layer, leaving a Ag layer adjacent to the Ni interconnect layer with limited reaction (BOL). The annealing data collected over 400 hours showed stability, indicating that the bonding is very good and the braze does not flow. Al—Si—Fe alloys and Al—Mg—Cr alloys were also tested as brazing materials. It was shown that the bonding must be carried out with Ti terminated interconnects and metallizations.

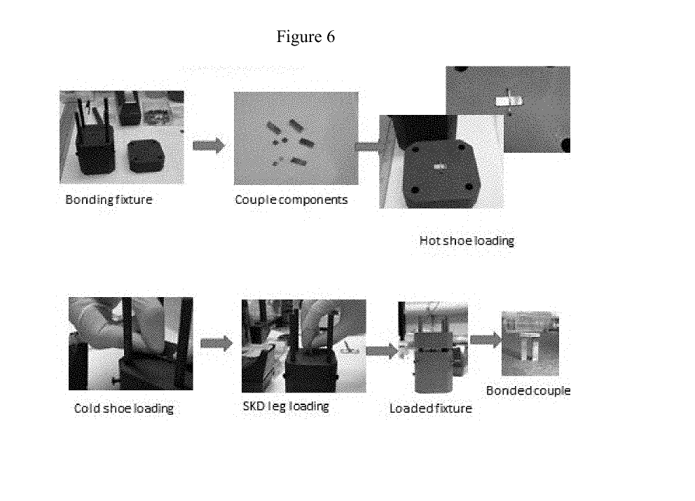

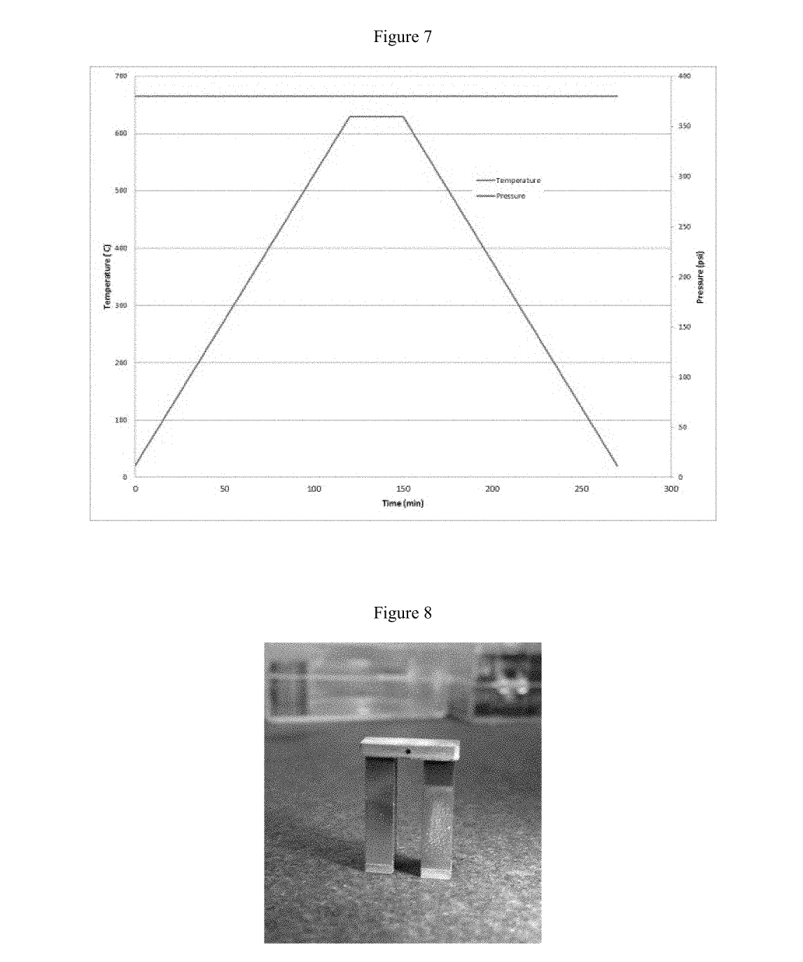

FIG. 6 depicts a typical process flow involved in fabricating the SKD thermocouple with braze joints. Ni electrodes were grinded so that they were flat and parallel to within 0.010 mm and finished with 1200 grit SiC paper. All the couple components (braze foils, SKD legs, electrodes) were cleaned by sonication in isopropanol for 2 minutes, followed by drying by wiping with tissue. The Ni hot electrode was loaded into the top plate cavity with CuSil-ABA braze foil layered on top. A Mo wire was used to secure the electrode and braze foil to the top plate of the bonding jig (see the top right image of FIG. 6: hot shoe loading). The p-type and n-type Ni cold electrodes were then loaded. The p-type and n-type cross-section CuSil-ABA braze foils were then loaded. Next, the p-type and n-type SKD legs were inserted. Each leg was gently depressed by about 1 mm to insure free movement with spring load. The bonding fixture top plate was carefully lowered down until contact is made between the hot shoe and SKD legs. The top place was gently depressed to about 1 mm to insure the assembly moved downward freely against spring load. Next, the bonding jig assembly was lowered into a braze furnace and about 10 lbs of static load (about 380 psi per leg) was applied. The assembly was then heated to 630° C. at 5° C./minute and held for 30 minutes at 630° C. Then, the assembly was cooled at 5° C./minute to room temperature (about 25° C.). The bonding profile is provided in FIG. 7. A vacuum level of 10⁻⁵ Torr was specified for couple bonding.

Although the foregoing invention has been described in some detail by way of illustration and Example for purposes of clarity of understanding, one of skill in the art will appreciate that certain changes and modifications may be practiced within the scope of the appended claims. In addition, each reference provided herein is incorporated by reference in its entirety to the same extent as if each reference was individually incorporated by reference. Where a conflict exists between the instant application and a reference provided herein, the instant application shall dominate.

What is claimed is:

1. A thermoelectric device comprising:
an interconnect layer;
a skutterudite layer; and
a metallization stack comprising a diffusion layer, wherein the metallization stack is disposed between and in electrical contact with the interconnect layer and the skutterudite layer.

2. The device of claim 1, wherein the interconnect layer comprises Ni.

3. The device of claim 1, wherein the interconnect layer has a thickness of from about 100 μm to about 10 mm.

4. The device of claim 1, wherein the skutterudite layer comprises a p-type skutterudite consisting of CeFe₃Ru₁Sb₁₂.

5. The device of claim 1, wherein the skutterudite layer comprises an n-type skutterudite consisting of Ce_{0.1}Co_{0.955}Pd_{0.045}Sb_{2.955}Te_{0.045}.

6. The device of claim 1, wherein the skutterudite layer has a thickness of from about 1 mm to about 100 mm.

7. The device of claim 1, wherein the diffusion layer comprises at least one metal selected from the group consisting of W, Nb, and CeSb.

8. The device of claim 1, wherein the diffusion layer has a thickness of from about 1 μm to about 100 μm.

9. The device of claim 1, wherein the metallization stack further comprises an adhesion layer disposed between and in electrical contact with the diffusion layer and the skutterudite layer.

10. The device of claim 9, wherein the adhesion layer comprises at least one metal selected from the group consisting of Mo, Nb, Ni and Ti.

11. The device of claim 9, wherein the adhesion layer has a thickness of from about 1 μm to about 100 μm.

12. The device of claim 1, wherein the metallization stack further comprises a capping layer disposed between and in electrical contact with the interconnect layer and the diffusion layer.

13. The device of claim 12, wherein the capping layer comprises at least one metal selected from the group consisting of Ti, Ni and stainless steel.

14. The device of claim 12, wherein the capping layer has a thickness of from about 1 μm to about 1000 μm.

15. The device of claim 1, wherein the device further comprises a braze joint disposed between and in electrical contact with the interconnect layer and the metallization stack.

16. The device of claim 15, wherein the braze joint comprises an alloy of Ag, Al, Cu, Ni, Si, Sn, Ti, In or combinations thereof.

17. The device of claim 15, wherein the braze joint comprises an alloy of Cu+Ag (CuSil), Cu+Ag+Ti (CuSil-ABA), Al+Si, Ni+Cu+Sn (Nicutin), Ag, and Sn.

18. The device of claim 1, comprising:
the interconnect layer consisting essentially of Ni;
a braze joint consisting essentially of CuSil-ABA, and in electrical contact with the interconnect layer;
the metallization stack comprising:
a capping layer consisting essentially of Ti, and in electrical contact with the braze joint;
the diffusion layer consisting essentially of W, and in electrical contact with the capping layer;
an adhesion layer consisting essentially of Ti, and in electrical contact with the diffusion layer; and
the skutterudite layer consisting essentially of CeFe₃Ru₁Sb₁₂, and in electrical contact with the adhesion layer

19. A method of preparing a SKD thermocouple, the method comprising:
contacting a skutterudite powder and a diffusion metal foil, at a temperature of at least about 600° C. and a pressure of from about 1000 psi to about 20,000 psi, thereby preparing the SKD thermocouple.

20. The method of claim 19, further comprising
an adhesion metal foil, wherein the adhesion metal foil is disposed between the diffusion metal foil and the skutterudite powder; and
a capping metal foil, wherein the capping metal foil is disposed on a side of the diffusion metal foil opposite the adhesion metal foil.

21. The method of claim 20, further comprising
contacting the SKD thermocouple with a braze metal foil, and an interconnect layer, wherein the braze metal foil is disposed between the SKD thermocouple and the interconnect layer, at a temperature of about 650° C. and a pressure of about 200 psi.

22. A method of preparing a braze joint, comprising
contacting an SKD thermocouple with a braze metal foil, and an interconnect layer, wherein the braze metal foil is disposed between the SKD thermocouple and the interconnect layer, at a temperature of about 650° C. and a pressure of about 200 psi.
